(19) United States
(12) Patent Application Publication
(10) Pub. No.: US 2006/0194356 A1
(43) Pub. Date: Aug. 31, 2006

(54) Method for manufacturing multi-wavelength semiconductor laser device

(75) Inventors: Keun Man Song, Seoul (KR); Su Yeol Lee, Sungnam (KR); Jin Chul Kim, Suwon (KR); Tae Jun Kim, Pyungtaek (KR); Chang Zoo Kim, Sungnam (KR); Sang Heon Han, Suwon (KR)

Correspondence Address: VOLPE AND KOENIG, P.C., UNITED PLAZA, SUITE 1600, 30 SOUTH 17TH STREET, PHILADELPHIA, PA, 19103, US

(73) Assignee: SAMSUNG ELECTRO-MECHANICS CO., LTD., Suwon (KR)

(21) Appl. No.: 11/238,319

(22) Filed: Sep. 29, 2005

(30) Foreign Application Priority Data
Feb. 28, 2005 (KR) 10-2005-16521

(51) Int. Cl. H01L 21/00

(52) U.S. Cl. 438/22

(57) ABSTRACT

The present invention provides a method for forming a multi-wavelength semiconductor laser device. The method comprises sequentially forming an AlGaAs-based epitaxial layer for a first semiconductor laser diode and an etching stop layer composed of AlxGayIn(1-x-y)P (0≦x≦1, 0≦y≦1) on a substrate and sequentially growing an n-type GaAs flattening buffer layer and an AlGaInP-based epitaxial layer for a second semiconductor laser diode on the substrate, after selectively removing the AlGaAs-based epitaxial layer and the etching stop layer.

### RELATED APPLICATION

The present invention is based on, and claims priority from, Korean Application Number 2005-016521, filed Feb. 28, 2005, the disclosure of which is incorporated by reference herein in its entirety.

### BACKGROUND OF THE INVENTION

1. Field of the Invention

The present invention generally relates to a multi-wavelength semiconductor laser device, and, more particularly, to a method for manufacturing a multi-wavelength semiconductor laser device, which can generate laser light at different wavelengths either simultaneously or selectively.

2. Description of the Related Art

Generally, a semiconductor laser device is a device which outputs light amplified through inductive emission, and the output light thereof has a narrow frequency width (monochromatic) and excellent directionality as well as high intensity. Due to such advantages, the semiconductor laser device has been spotlighted as an optical source for an optical pick-up device of optical disk systems, such as CD players, DVD players and the like.

Recently, in the field of optical disk technology, it has been required to provide multi-wavelength semiconductor laser devices which can generate light having different wavelengths. As a representative example of the multi-wavelength semiconductor laser devices, there is a two-wavelength semiconductor laser device used for a CD-reproducing apparatus (780 nm) for relatively low density data storage and for a DVD-reproducing apparatus (635 nm or 650 nm) for relatively high density data storage.

FIGS. 1a to 1f are step diagrams illustrating a conventional method for manufacturing a two-wavelength semiconductor laser device. In FIGS. 1a to 1f, the method for manufacturing the conventional two-wavelength semiconductor laser device which has a first AlGaAs-based semiconductor laser diode (for generating light having a wavelength of 780 nm) and a second AlGaInP-based semiconductor laser diode (for generating light having a wavelength of 650 nm) implemented in a monolithic shape on a single substrate is shown.

First, as shown in FIG. 1a, epitaxial layers for the first semiconductor laser diode are formed on an n-type GaAs substrate 11. That is, an n-type GaAs buffer layer 12a, an n-type AlGaAs clad layer 13a, an AlGaAs active layer 14a, a p-type AlGaAs clad layer 15a, and a p-type cap layer 16a are sequentially formed on the n-type GaAs substrate 11.

Then, as shown in FIG. 1b, some portion of an upper surface of the GaAs substrate 11 is exposed by selectively removing the epitaxial layers 12a, 13a, 14a, 15a and 16a through a photolithography process and an etching process.

Then, as shown in FIG. 1c, other epitaxial layers for the second semiconductor laser diode are formed on the exposed upper surface of the GaAs substrate 11. That is, an n-type AlGaInP clad layer 13b, an AlGaInP active layer 14b, a p-type AlGaInP clad layer 15b, and a p-type cap layer 16b are sequentially formed thereon.

Next, as shown in FIG. 1d, the epitaxial layers 13b, 14b, 15b and 16b of the second semiconductor laser diode on the upper surface of the epitaxial layer 16a of the first semiconductor laser diode are removed, and at the same time, some portion of the epitaxial layers 13b, 14b, 15b and 16b of the second semiconductor laser diode is removed to form two separated epitaxial structures by additional photolithography and etching processes.

Subsequently, as shown in FIG. 1e, ridge structures for enhancing current injection efficiency are formed in the p-type AlGaAs clad layer 15a and the p-type AlGaInP clad layer 15b, respectively, by selectively etching the p-type AlGaAs clad layer 15a and the p-type AlGaInP clad layer 15b through typical methods.

Finally, as shown in FIG. 1f, current blocking layers 18a and 18b are formed using a dielectric material on upper surfaces of the p-type clad layers 15a and 15b where the ridge structures are formed, and after exposing the respective cap layers by use of the photolithography process and etching process, p-side electrodes 19a and 19b are formed on the exposed p-type cap layers 16a and 16b, and an n-side electrode 18 is formed under the bottom of the GaAs substrate 11.

As such, the two semiconductor laser diodes 10a and 1b for generating light having different wavelengths are formed on the same substrate 11, whereby a single-chip two-wavelength semiconductor laser device 10 can be realized.

However, in the method for manufacturing the conventional two-wavelength semiconductor laser device, high selectivity for the AlGaAs-based epitaxial layers 13a, 14a, 15a and 16a of the first semiconductor laser diode and the GaAS substrate 11 is not ensured. Thus, the surface of the substrate which continuously grows as a growth plane for the second semiconductor laser diode is liable to be damaged during the etching process as shown in FIG. 1b, whereby an excellent crystal cannot be formed during the secondary growth process.

Moreover, even if an n-type GaInP buffer (not shown) is additionally formed, the secondarily grown epitaxial layers have a significantly reduced crystallinity since the second semiconductor laser diode is formed on the surface of the substrate already damaged by the etching process, resulting in deteriorated reliability of the second semiconductor laser diode.

As such, it has been believed that bad surface morphology for growth of the second semiconductor laser diode causes problems when manufacturing a multi-wavelength semiconductor laser device.

### SUMMARY OF THE INVENTION

The present invention has been made to solve the above problems, and it is an object of the present invention to provide a method for manufacturing a multi-wavelength semiconductor laser device, which provides an additional n-type GaAs flattening buffer layer after a primary wet etching process, thereby enhancing the quality of a secondary growth plane for an AlGaInP-based epitaxial layer.

In accordance with one aspect of the present invention, the above and other objects can be accomplished by the provision of a method for manufacturing a multi-wavelength semiconductor laser device, comprising the steps of: preparing a substrate having an upper surface divided into at least first and second regions; sequentially forming an AlGaAs-based epitaxial layer for a first semiconductor laser diode and an etching stop layer composed of AlxGayIn(1-x-y)P (0≦x≦1, 0≦y≦1) on the substrate; selectively removing the AlGaAs-based epitaxial layer and the etching stop layer from the second region of the substrate; sequentially growing an n-type GaAs flattening buffer layer and an AlGaInP-based epitaxial layer for a second semiconductor laser diode on the substrate; selectively removing the AlGaInP-based epitaxial layer located on the AlGaAs-based epitaxial layer; sequentially removing the n-type GaAs flattening buffer layer and the etching stop layer from the AlGaAs-based epitaxial layer; and separating the AlGaAs-based epitaxial layer and the AlGaInP-based epitaxial layer.

Preferably, the etching stop layer is an un-doped layer, and the n-type GaAs flattening buffer layer has a thickness of at least 10 Å. More preferably, in order to sufficiently flatten a growth plane for the secondary epitaxial layer, the n-type GaAs flattening buffer layer has a thickness in the range of 0.8˜1.2 μm.

Preferably, the step of sequentially removing the n-type GaAs flattening buffer layer and the etching stop layer comprises wet etching the n-type GaAs flattening buffer layer by use of a sulfuric acid-based or ammonia-based etchant, and wet etching the etching stop layer by use of a hydrochloric acid-based or phosphoric acid-based etchant.

Preferably, the step of separating the AlGaAs-based epitaxial layer and the AlGaInP-based epitaxial layer comprise removing the n-type GaAs flattening buffer layer remaining on a side surface of the AlGaAs-based epitaxial layer.

Preferably, the AlGaAs-based epitaxial layer and the AlGaInP-based epitaxial layer for the first and second semiconductor laser diodes comprise n-type clad layers, active layers and p-type clad layers, respectively, in which each of the layers has its own composition in either the AlGaAs-based epitaxial layer or the AlGaInP-based epitaxial layer. In this case, preferably, the method further comprises the step of forming upper portions of the p-type clad layers of the respective epitaxial layers for the first and second semiconductor laser diodes into ridge structures after separating the AlGaAs-based epitaxial layer and the AlGaInP-based epitaxial layer.

The present invention is characterized in that the n-type GaAs flattening buffer layer is additionally formed after the primary wet etching, thereby enhancing the quality of the secondary growth plane for the AlGaInP-based epitaxial layer. With regard to this, as a process for selectively removing the GaAs flattening buffer layer on the epitaxial layer for the first semiconductor laser diode, the method of the invention comprises the step of forming the etching stop layer composed of AlₓGa_{y}In_{(1-x-y)}P (0≦x≦1, 0≦y≦1) on the epitaxial layer upon the growth of the primary epitaxial layer.

### BRIEF DESCRIPTION OF THE DRAWINGS

The foregoing and other objects and features of the present invention will be more clearly understood from the following detailed description taken in conjunction with the accompanying drawings, in which:

FIGS. 1a to 1f are step diagrams illustrating a conventional method for manufacturing a two-wavelength semiconductor laser device;

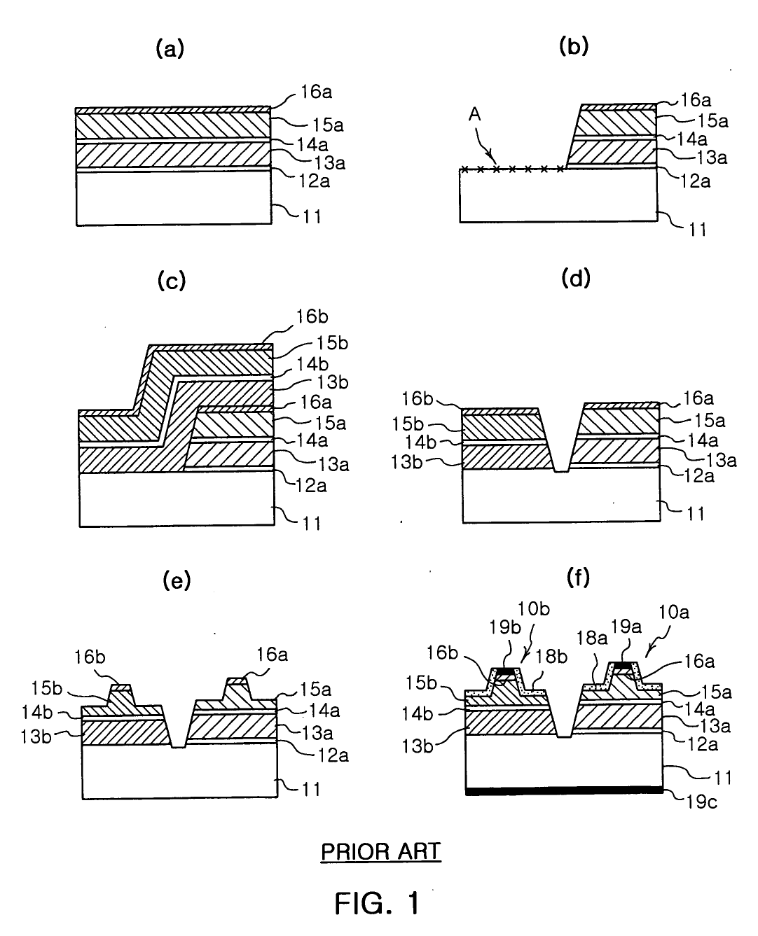

FIGS. 2a to 2h are step diagrams illustrating a method for manufacturing a two-wavelength semiconductor laser device according to one embodiment of the present invention; and

FIGS. 3a and 3b are AFT micrographs showing surfaces of substrates provided for a secondary growth process in the conventional method and in the method of the invention, respectively.

### DESCRIPTION OF THE PREFERRED EMBODIMENTS

Preferred embodiments will now be described in detail with reference to the accompanying drawings.

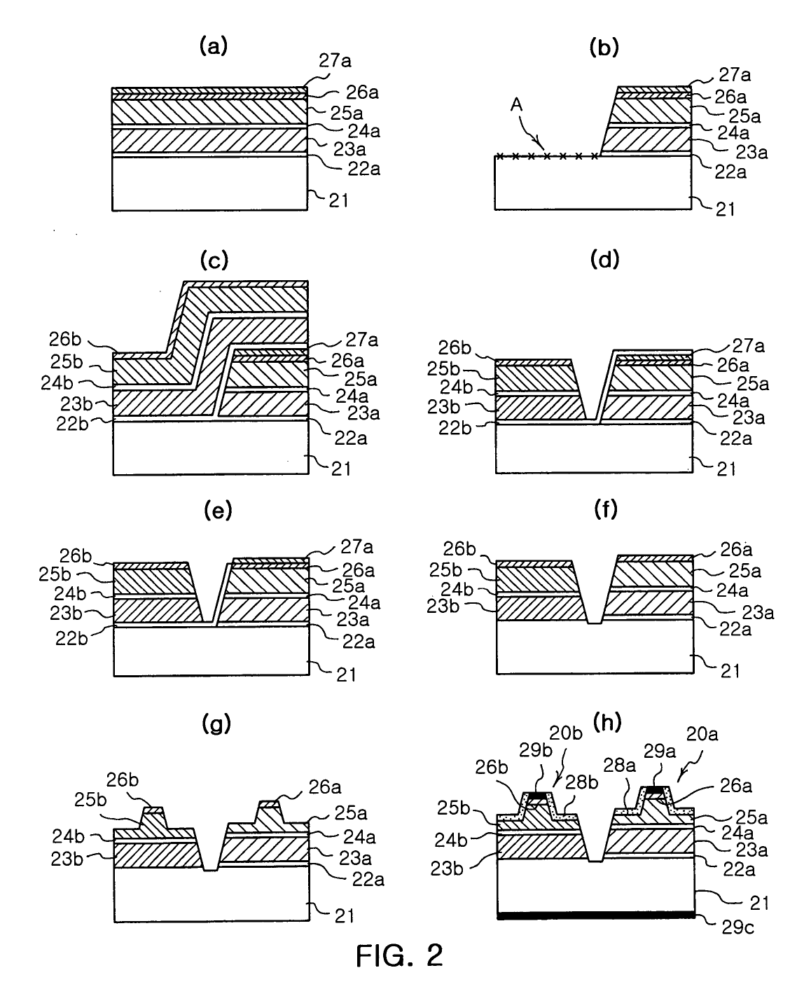

FIGS. 2a to 2h are step diagrams illustrating a method for manufacturing a two-wavelength semiconductor laser device according to one embodiment of the present invention. In FIGS. 2a to 2h, the method for manufacturing the two-wavelength semiconductor laser device of the invention, in which a first semiconductor laser diode for generating light having a wavelength of 780 nm and a second semiconductor laser diode for generating light having a wavelength of 650 nm are implemented on a single substrate 21.

First, as shown in FIG. 2a, as a primary growth process, AlGaAs-based epitaxial layers 22a, 23a, 24a, 25a and 26a for a first semiconductor laser diode, and an etching stop layer 27a composed of AlₓGa_{y}In_{(1-x-y)}P (0≦x≦1, 0≦y≦1) are sequentially formed on the substrate 21. The substrate 21 is an n-type GaAs substrate, and has an upper surface divided into a first region and a second region on which at least two semiconductor laser diodes are formed. The primary growth process, that is, the process for growing the AlGaAs-based epitaxial layers is performed by sequentially growing an n-type GaAs buffer layer 22a, an n-type AlGaAs clad layer 23a, a GaAs active layer 24, a p-type AlGaAs clad layer 25a, and a p-type cap layer 26a. Here, the etching stop layer 27a is employed for easily removing a GaAs flattening buffer layer, which will be formed by a succeeding process, and preferably, it is not doped with an impurity in order to avoid influence on other layers due to the particular conductivity type impurity. As to the composition of the etching stop layer, some portion of P content thereof may be substituted with As under condition of ensuring selection to GaAs composition during a wet etching process.

Then, as shown in FIG. 2b, the AlGaAs-based epitaxial layers 22a, 23a, 24a, 25a and 26a, and the etching stop layer 27a are selectively removed from the second region of the substrate 21, that is, the region where the second semiconductor laser diode will be formed. This can be performed through a photolithography process and a selective wet etching process using photolithography. Here, the wet etching process may comprise a selective wet etching process for the etching stop layer 27a using a sulfuric acid-based or ammonia-based etchant, and a selective wet etching process for the AlGaAs-based epitaxial layers 22a, 23a, 24a, 25a and 26a using a hydrochloric acid-based or phosphoric acid-based etchant.

Then, as shown in FIG. 2c, as a secondary growth process, an n-type GaAs flattening buffer layer 22b, and AlGaInP-based epitaxial layers 23b, 24b, 25b and 26b for the second semiconductor laser diode are sequentially grown on the substrate 21. At this time, the n-type flattening buffer layer 22b may be additionally formed on the substrate 21 in order to enhance a state of the wet-etched surface of the second region before the secondary growth of the AlGaInP-based epitaxial layers. The n-type flattening buffer layer 22b may be grown to a thickness of at least 10 Å on the surface of the second region damaged by wet etching. When the n-type buffer layer 22b is grown to a thickness of 0.8 μm or more, sufficient flattening effect can be expected, whereas when the buffer layer 22b is grown to a thickness greater than 1.2 μm, accurate alignment between two semiconductor laser diodes on the active layers becomes difficult. Accordingly, it is desirable to form the n-type buffer layer 22b to a thickness of about 0.8˜1.2 μm.

Since the AlGaInP-based epitaxial layers 23b, 24b, 25b and 26b subsequently grown on the n-type GaAs flattening buffer layer 22b are grown on a flattened growth plane having a good quality, these layers have good crystallinity. The AlGaInP-based epitaxial layers grown by the secondary growth process may comprise an n-type AlGaInP clad layer 23b, an AlGaP active layer 24b, a p-type AlGaInP clad layer 25b, and a p-type cap layer 26b. Here, the AlGaInP-based epitaxial layers may be formed not only on the desired second region of the substrate 21 but also above the AlGaAs-based epitaxial layers 22a, 23a, 24a, 25a and 26a remaining for the first semiconductor laser diode.

Then, as shown in FIG. 2d, the AlGaInP-based epitaxial layers 23b, 24b, 25b and 26b located above the AlGaAs-based epitaxial layers 22a, 23a, 24a, 25a and 26a are selectively removed. This can be performed through a lift-off process. With this process, although separation between the epitaxial layers of the first and second regions can be achieved to some extent, electrical disconnection between the epitaxial layers of the first and second regions cannot be completely achieved. In the present invention, due to the n-type GaAs flattening buffer layer 22b, the AlGaInP-based epitaxial layers 23b, 24b, 25b and 26b frequently fail to be completely removed from above the AlGaAs-based epitaxial layers 22a, 23a, 24a, 25a and 26a during the etching process. Thus, the AlGaInP-based epitaxial layers 23b, 24b, 25b and 26b are completely removed from above AlGaAs-based epitaxial layers 23a, 24a, 25a and 26a by an additional diode separating process as shown in FIG. 2f, which will be described below.

Then, the n-type GaAs flattening buffer layer 22b and the etching stop layer 27a are sequentially removed from the AlGaAs-based epitaxial layers 23a, 24a, 25a and 26a.

In this step, the n-type GaAs flattening buffer layer is wet-etched by use of the hydrochloric acid-based or phosphoric acid-based etchant. In this case, since the etching stop layer 27a composed of AlₓGa_{y}In_{(1-x-y)}P (0≦x≦1, 0≦y≦1) is formed on the primarily grown AlGaAs-based epitaxial layer 26a, the AlGaAs-based epitaxial layers 23a, 24a, 25a and 26a are prevented from being damaged.

Then, as shown in FIG. 2f, wet etching is performed on the etching stop layer 27a and an intermediate region between the AlGaInP-based epitaxial layers 23b, 24b, 25b and 26b and the AlGaAs-based epitaxial layers 23a, 24a, 25a and 26a so as to completely separate the AlGaAs-based epitaxial layers and the AlGaInP-based epitaxial layers of the first and second regions. Wet etching of the etching stop layer is performed by use of the hydrochloric acid-based or phosphoric acid-based etchant having a high selectivity against AlGaAs without damaging the AlGaAs-based epitaxial layers 23a, 24a, 25a and 26a. Additionally, the process of completely separating the AlGaAs-based epitaxial layers 23a, 24a, 25a and 26a and the AlGaInP-based epitaxial layers 23b, 24b, 25b and 26b may comprise removing the n-type GaAs flattening buffer layer 22b remaining on side surfaces of the AlGaAs-based epitaxial layers 23a, 24a, 25a and 26a.

Then, as shown in FIG. 2g, the p-type AlGaAs clad layer 25a and the p-type AlGaInP clad layer 25b are selectively etched by use of a well-known method to form ridge structures. Although not shown in FIGS. 2a and 2c, the step of forming the ridge structures in the p-type AlGaAs clad layer 25a and the p-type AlGaInP clad layer 25b, respectively, may be easily performed by forming additional etching stop layers within the p-type AlGaAs clad layer 25a and the p-type AlGaInP clad layer where the ridge structures will be defined.

Finally, as shown in FIG. 2h, current blocking layers 28a and 28b are formed of a dielectric material on upper surfaces of the p-type clad layers 25a and 25b where the ridge structures are formed, and after exposing the respective p-type cap layers 26a and 26b by use of the photolithography process and etching process, p-side electrodes 29a and 29b are formed on exposed surfaces of the p-type cap layers 26a and 26b, and an n-side electrode 29c is formed under the bottom of the GaAs substrate 21. Generally, the p-side electrodes 29a and 29b may be formed of Ti, Pt, At or alloys thereof, and the n-side electrode 29c may be formed of Au/Ge, Au, Ni or alloys thereof.

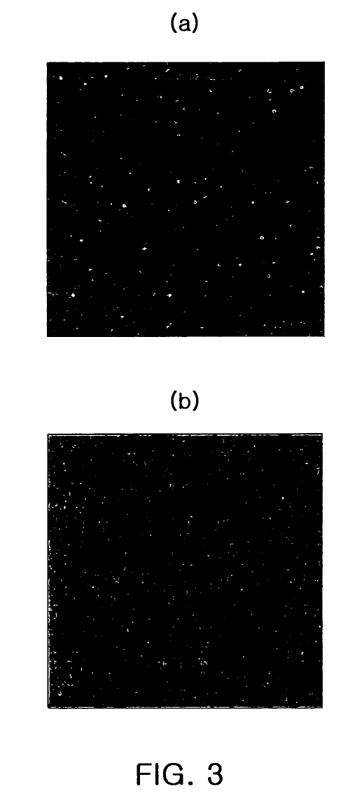

FIGS. 3a and 3b are AFT micrographs showing surfaces of substrates provided for a secondary growth process in the conventional method and in the method of the invention, respectively, in which the surface of the substrate according to the invention is formed with the n-type GaAs flattening buffer layer 22b of FIG. 2b. In the AFT micrographs, a difference in brightness shows a difference in height on the surfaces of the substrates.

As can be seen from FIG. 3a, the surface of the substrate achieved by the conventional method has a large difference in brightness and is significantly non-uniform. As described above, this shows a result of the primary etching process damaging the surface of the substrate. According to the measurements, the surface of the substrate of FIG. 3a has a Root Means Square (RMS) roughness of 5˜10 Å.

On the other hand, as shown in FIG. 3b, it can be seen that the surface of the substrate achieved by the method of the invention has a small difference in brightness, and spotted portions are rarely shown on the surface thereof. This is because the n-type flattening buffer layer is additionally formed after the secondary wet etching process. According to the measurements, the surface of the substrate of FIG. 3b has a Root Means Square (RMS) roughness of about 2.0 Å, which is remarkably reduced in comparison to that of FIG. 3a.

As illustrated in FIGS. 2a to 2h, such an n-type GaAs flattening buffer layer can be achieved since the additional etching stop layer composed of AlₓGa_{y}In_{(1-x-y)}P (0≦x≦1, 0≦y≦1) is formed on the AlGaAs-based epitaxial layers during the primary growth process. More specifically, if the n-type GaAs flattening buffer layer is grown without forming the etching stop layer composed of AlₓGa_{y}In_{(1-x-y)}P (0≦x≦1, 0≦y≦2), the n-type GaAs flattening buffer layer is grown on the p-type GaAs cap layer having a similar etching rate to that of the n-type GaAs flattening buffer layer, and thus it becomes significantly difficult to selectively remove only the n-type GaAs flattening buffer layer from the first light emitting portion. However, according to the present invention, the etching stop layer composed of AlₓGa_{y}In_{(1-x-y)}P (0≦x≦1, 0≦y≦1) is formed on the AlGaAs-based epitaxial layers, so that the n-type GaAs flattening buffer layer grown for the secondary epitaxial layer growth can be easily removed from above the AlGaAs-based epitaxial layers.

As apparent from the above description, according to the present invention, the etching stop layer composed of AlₓGa_{y}In_{(1-x-y)}P (0≦x≦1, 0≦y≦1) is formed along with the n-type GaAs flattening buffer layer on the first light emitting portion, thereby allowing the AlGaInP-based epitaxial layers having excellent crystallinity to be formed, while allowing the unnecessary n-type GaAs flattening buffer layer remaining on the AlGaInP-based epitaxial layers to be removed using the etching stop layer in the succeeding step.

It should be understood that the embodiments and the accompanying drawings have been described for illustrative purposes and the present invention is limited only by the following claims. Further, those skilled in the art will appreciate that various modifications, additions and substitutions are allowed without departing from the scope and spirit of the invention as set forth in the accompanying claims.

What is claimed is:

1. A method for manufacturing a multi-wavelength semiconductor laser device, comprising the steps of:
preparing a substrate having an upper surface divided into at least first and second regions;
sequentially forming an AlGaAs-based epitaxial layer for a first semiconductor laser diode and an etching stop layer composed of AlxGayIn(1-x-y)P (0≦x≦1, 0≦y≦1) on the substrate;
selectively removing the AlGaAs-based epitaxial layer and the etching stop layer from the second region of the substrate;
sequentially growing an n-type GaAs flattening buffer layer and an AlGaInP-based epitaxial layer for a second semiconductor laser diode on the substrate;
selectively removing the AlGaInP-based epitaxial layer located above the AlGaAs-based epitaxial layer;
sequentially removing the n-type GaAs flattening buffer layer and the etching stop layer from the AlGaAs-based epitaxial layer; and
separating the AlGaAs-based epitaxial layer and the AlGaInP-based epitaxial layer.

2. The method as set forth in claim 1, wherein the etching stop layer is an un-doped layer.

3. The method as set forth in claim 2, wherein the n-type GaAs flattening buffer layer has a thickness of at least 10 Å.

4. The method as set forth in claim 1, wherein the n-type GaAs flattening buffer layer has a thickness in the range of 0.8˜1.2 μm.

5. The method as set forth in claim 1, wherein the step of sequentially removing the n-type GaAs flattening buffer layer and the etching stop layer comprises wet etching the n-type GaAs flattening buffer layer by use of a sulfuric acid-based or ammonia-based etchant, and wet etching the etching stop layer by use of a hydrochloric acid-based or phosphoric acid-based etchant.

6. The method as set forth in claim 1, wherein the step of separating the AlGaAs-based epitaxial layer and the AlGaInP-based epitaxial layer comprises removing the n-type GaAs flattening buffer layer remaining at a side surface of the AlGaAs-based epitaxial layer.

7. The method as set forth in claim 1, wherein the AlGaAs-base epitaxial layer and the AlGaInP-base epitaxial layer for the first and second semiconductor laser diodes comprise n-type clad layers, active layers and p-type clad layers, respectively, each of the layers having its own composition in either the AlGaAs-base epitaxial layer or the AlGaInP-base epitaxial layer.

8. The method as set forth in claim 7, further comprising the step of:
forming upper portions of the p-type clad layers of the respective epitaxial layers for the first and second semiconductor laser diodes into ridge structures after the step of separating the AlGaAs-based epitaxial layer and the AlGaInP-based epitaxial layer.

9. The method as set forth in claim 1, wherein the etching stop layer comprises As substituting some portion of P content.
